(19) United States
(12) Patent Application Publication
(10) Pub. No.: US 2011/0114164 A1
(43) Pub. Date: May 19, 2011

(54) HIGH EFFICIENCY SOLAR CELL

(76) Inventors: Yi-Chieh Lin, (US); Shih-Chang Lee, (US)

(21) Appl. No.: 12/948,279

(22) Filed: Nov. 17, 2010

(30) Foreign Application Priority Data
Nov. 17, 2009 (TW) 098139083
Dec. 22, 2009 (TW) 098144415

(51) Int. Cl. H01L 31/06

(52) U.S. Cl. 136/255

(57) ABSTRACT

Disclosed is a solar cell including a first base layer, a second base layer on the first base layer, and an emitter layer on the second base layer. Furthermore, a window layer may be disposed on the emitter, and/or a back surface field (BSF) layer may be disposed under the first base layer.

### TECHNICAL FIELD

The application relates to an optoelectronic device, and more particularly to a high efficiency solar cell.

### REFERENCE TO RELATED APPLICATION

This application claims the right of priority based on Taiwan application Ser. No. 098144415, filed on Dec. 22, 2009, and Taiwan Patent Application No. 098139083, filed on Nov. 17, 2009, the entirety of which is incorporated by reference herein.

### DESCRIPTION OF BACKGROUND ART

Optoelectronic devices include several categorizations such as light-emitting diodes, solar cells, photo diodes, and the likes. Environmental protection consciousness is enhanced because fossil fuel is continuously decreased, so alternative energies and renewable energies are intensively researched. The most highlight of those energies is a solar cell because it may directly converse solar energy to electrical energy. The described photo-electrical conversion is free of hazard, such as carbon dioxide or nitride, and does not pollute the environment. Triple junction solar cells of InGaP/GaAs/Ge have the most potential in development, however, the energy conversion efficiency thereof does not achieve the optimum value yet, and one of the reasons is that gap differences between InGaP, GaAs, and Ge can not match the current. For example, a conventional solar cell includes a top cell of InGaP, a middle cell of GaAs, and a bottom cell of Ge. The top cell of InGaP has a band gap of about 1.85 eV to produce a current density of 18 mA/cm² to 20 mA/cm², the middle cell of GaAs has a band gap of about 1.405 eV to produce a current density of 14 mA/cm² to 16 mA/cm², and the bottom cell of Ge has a band gap of 0.67 eV to produce a current density of 26 mA/cm² to 30 mA/cm². The current produced by the middle cell is too low to match the current produced by the top cell and the bottom cell, such that current, voltage, and energy conversion efficiency of the solar cell are reduced.

The optoelectronic devices such as the described solar cell may include a substrate and electrodes. The substrate can be further connected to a base by solder or gel for forming a light-emitting device or a light-absorbing device. In addition, the base includes a circuit electrically connected to the electrodes of the optoelectronic device. The electrical connection can be an electrically conductive structure, such as a metal line.

### SUMMARY OF THE DISCLOSURE

A solar cell in accordance with an embodiment of the application includes a first base layer selected from a group consisting of a GaAs₍₁₋ₓ₎Sbₓ base layer, a GaAs_{(1-y)}N_{y} base layer, and a GaAs_{(1-z)}In_{z} base layer, wherein each of x, y, and z is a real number less than 1 and greater than 0; a GaAs-based base layer on the first base layer; and a GaAs-based emitter layer on the GaAs-based base layer.

A solar cell in accordance with an embodiment of the application includes a first base layer; a second base layer on the first base layer; and an emitter layer on the second base layer, wherein the conduction band of the first base layer is higher than the conduction band of the second base layer, and the band gap of the first base layer is less than the band gap of the second base layer.

### BRIEF DESCRIPTION OF THE DRAWINGS

FIG. 1 illustrates a cross section of a solar cell in accordance with a first embodiment of the application;

FIG. 2 illustrates a band diagram of a first base layer and a second base layer of the solar cell in accordance with the first embodiment of the application; and

FIG. 3 illustrates a cross section of another solar cell in accordance with a second embodiment of the application.

### DETAILED DESCRIPTION OF PREFERRED EMBODIMENTS

The embodiments are described hereinafter in accompany with drawings.

As shown in FIG. 1, a solar cell 1 in accordance with the first embodiment includes a back surface field layer 10, a first base layer 12 on the back surface field layer 10, a second base layer 14 on the first base layer 12, an emitter layer 16 on the second base layer 14, and a window layer 17 on the emitter layer 16. In the solar cell 1, the first base layer 12, the second base layer 14, and the emitter layer 16 are electrically conductive, such as an n-type semiconductor or a p-type semiconductor. The polarity of the first and second base layers is different from that of the emitter layer 16.

The first base layer 12 and the second base layer 14 may absorb light to produce electrons and holes. The junction between the second base layer 14 and the emitter layer 16 forms a built-in field, such that the electrons and the holes are driven to flow toward the window layer 17 and the back surface field layer 10 respectively to produce current.

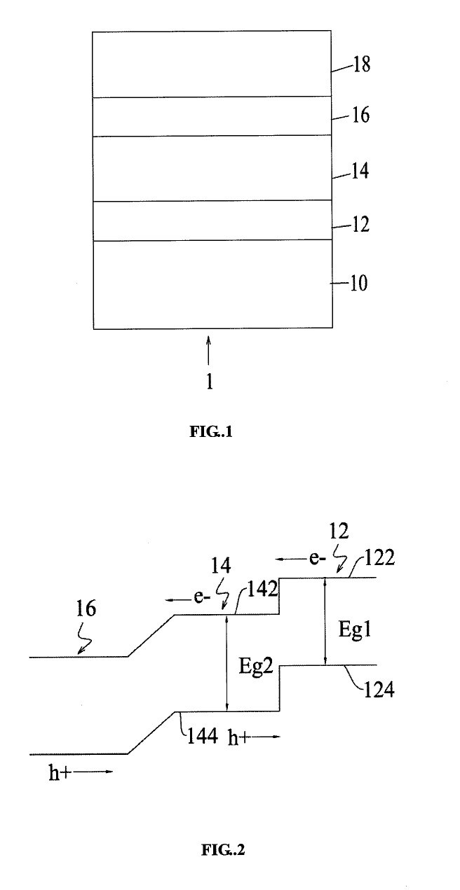

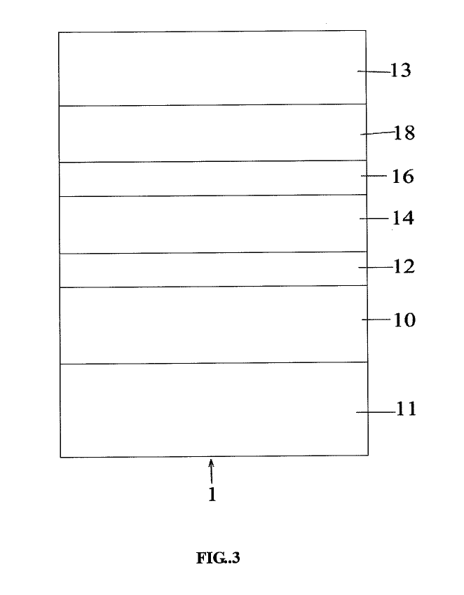

The band diagram of the first base layer 12 and the second base layer 14 is shown in FIG. 2. The band gap E_{g}1 of the first base layer 12 is less than the band gap E_{g}2 of the second base layer 14. Therefore, the absorption of the light in long wavelength in the solar cell is enhanced, and the current density produced by the solar cell is increased to about 18 mA/cm² to 20 mA/cm². The conduction band 122 of the first base layer 12 is higher than the conduction band 142 of the second base layer 14, and the valance band 124 of the first base layer 12 is higher than the valance band 144 of the second base layer 14, so the carriers produced by the first base layer 12 and the second base layer 14 may flow smoothly. In one embodiment, the first base layer 12 can be GaAs₍₁₋ₓ₎Sbₓ, wherein x is a real number greater than 0 and less than 1, preferably greater than 0.1 and less than 0.25. In another embodiment, the first base layer 12 can be GaAs_{(1-y)}N_{y}, wherein y is a real number greater than 0 and less than 1, preferably greater than 0.01 and less than 0.09. In a further embodiment, the first base layer 12 can be GaAs_{(1-z)}In_{z}, wherein z is a real number greater than 0 and less than 1, preferably greater than 0.1 and less than 0.3. The first base layer 12 has a greater doping concentration than that of the second base layer 14. For example, the second base layer 14 has a p-type doping concentration of about 1×10¹⁷ cm⁻³, and the first base layer 12 has a p-type doping concentration of about 2×10¹⁷ cm⁻³, preferably of greater than about 5×10¹⁷ cm⁻³. The second base layer 14 can be GaAs-based base layer, such as GaAs or InGaAs.

The band gap of the back surface field layer 10 is greater than the band gap E_{g}1 of the first base layer 12 to block the electrons. The back surface field layer 10 can be AlᵤGa₍₁₋ᵤ₎As or AlᵤInᵥGa₍₁₋ᵤ₋ᵥ₎P, wherein each of u and v is a real number greater than or equal to 0 and less than or equal to 1. The emitter layer 16 may absorb light to form electrons and holes. The junction between the second base layer 14 and the emitter layer 16 forms a built-in field, such that the electrons and the holes are driven to flow toward the window layer 17 and the back surface field layer 10 respectively to produce current. The emitter layer 16 can be GaAs-based emitter layer, such as GaAs or InGaAs. The band gap of the window layer 18 is greater than the band gap of the emitter layer 16 to block the electron. The window layer 18 can be AlᵤGa₍₁₋ᵤ₎As or AlᵤInᵥGa₍₁₋ᵤ₋ᵥ₎P, wherein each of u and v is a real number greater than or equal to 0 and less than or equal to 1.

FIG. 3 shows a cross section of another solar cell in accordance with a second embodiment of the application. The solar cell includes a back surface field layer 10, a bottom cell of Ge 11 under the back surface field layer 10, a window layer 18, and a top cell of GaInP 13 on the window layer 18. The solar cell in the first embodiment serves as a middle cell in the second embodiment. In the second embodiment, the top cell of InGaP 13 produces a current density of about 18 mA/cm² to 20 mA/cm², the bottom cell of Ge 11 produces a current density of 26 mA/cm² to 30 mA/cm², and the middle cell produces a current density of 18 mA/cm² to 20 mA/cm². Comparing with the conventional solar cell as described above, the currents produced by the middle cell, the bottom cell of Ge 11, and the top cell of InGaP 13 are matched and have less differences. Therefore, the loss of current and voltage is avoided, and the energy conversion efficiency of the solar cell 1 is improved.

The foregoing description has been directed to the specific embodiments of this invention. It will be apparent; however, that other alternatives and modifications may be made to the embodiments without escaping the spirit and scope of the invention.

What is claimed is:

1. A solar cell, comprising:
a first base layer selected from a group consisting of a GaAs₍₁₋ₓ₎Sbₓ, base layer, a GaAs_{(1-y)}N_{y} base layer, and a GaAs_{(1-z)}In_{z} base layer, wherein each of x, y, and z is a real number less than 1 and greater than 0;
a GaAs-based base layer on the first base layer; and
a GaAs-based emitter layer on the GaAs-based base layer.

2. The solar cell as claimed in claim 1, wherein x is greater than 0.1 and less than 0.25.

3. The solar cell as claimed in claim 1, wherein y is greater than 0.01 and less than 0.09.

4. The solar cell as claimed in claim 1, wherein z is greater than 0.1 and less than 0.3.

5. The solar cell as claimed in claim 1, wherein the GaAs-based base layer comprises InGaAs or GaAs.

6. The solar cell as claimed in claim 1, wherein the valence band of the GaAs₍₁₋ₓ₎Sbₓ base layer is higher than the valance band of the GaAs-based base layer, the conduction band of the GaAs₍₁₋ₓ₎Sbₓ base layer is higher than the conduction band of the GaAs-based base layer, and the band gap of the GaAs₍₁₋ₓ₎Sbₓ, Sbₓ base layer is less than the band gap of the GaAs-based base layer.

7. The solar cell as claimed in claim 1, wherein the conduction band of the GaAs_{(1-y)}N_{y} base layer is higher than the conduction band of the GaAs-based base layer, and the band gap of the GaAs_{(1-y)}N_{y} base layer is less than the band gap of the GaAs-based base layer.

8. The solar cell as claimed in claim 1, wherein the conduction band of the GaAs_{(1-z)}In_{z} base layer is higher than the conduction band of the GaAs-based base layer, and the band gap of the GaAs_{(1-z)}In_{z} base layer is less than the band gap of the GaAs-based base layer.

9. The solar cell as claimed in claim 1, further comprising a back surface field layer under the first base layer, wherein the band gap of the back surface field layer is greater than the band gap of the first base layer.

10. A solar cell, comprising:
a first base layer;
a second base layer on the first base layer; and
an emitter layer on the second base layer,
wherein the conduction band of the first base layer is higher than the conduction band of the second base layer, and the band gap of the first base layer is less than the band gap of the second base layer.

11. The solar cell as claimed in claim 10, wherein the second base layer comprises GaAs or InGaAs.

12. The solar cell as claimed in claim 10, further comprising a back surface field layer under the first base layer, wherein the band gap of the back surface field layer is greater than the band gap of the first base layer.

13. The solar cell as claimed in claim 10, wherein the valence band of the first base layer is higher than the valence band of the second base layer, and the band gap of the first base layer is less than the band gap of the second base layer.

14. The solar cell as claimed in claim 10, wherein the first base layer comprises GaAs₍₁₋ₓ₎Sbₓ, GaAs_{(1-y)}N_{y}, and GaAs_{(1-z)}In_{z}, wherein each of x, y, and z is a real number less than 1 and greater than 0.

15. The solar cell as claimed in claim 14, wherein x is greater than 0.1 and less than 0.25.

16. The solar cell as claimed in claim 14, wherein y is greater than 0.01 and less than 0.09.

17. The solar cell as claimed in claim 14, wherein z is greater than 0.1 and less than 0.3.

18. The solar cell as claimed in claim 10, wherein the first base layer has a higher doping concentration than that of the second base layer.

19. The solar cell as claimed in claim 10, wherein the first base layer has a doping concentration of about 2×10¹⁷ cm⁻³.
